(19) United States
(12) Patent Application Publication
(10) Pub. No.: US 2026/0190637 A1
(43) Pub. Date: Jul. 2, 2026

(54) DISPLAY DEVICE AND ELECTRONIC DEVICE INCLUDING THE SAME

(71) Applicant: Samsung Display Co., LTD., Yongin-si (KR)

(72) Inventor: SEUNGUK NOH, Yongin-si (KR)

(21) Appl. No.: 19/307,620

(22) Filed: Aug. 22, 2025

(30) Foreign Application Priority Data
Dec. 27, 2024 (KR) 10-2024-0198633

(51) Int. Cl. H10K 59/122; H10K 50/115; H10K 102/00

(52) U.S. Cl. CPC H10K 59/122; H10K 50/115; H10K 2102/351

(57) ABSTRACT

A display device includes: a first electrode disposed in a light-emitting area on a substrate, a pixel defining layer covering an edge of the first electrode and defining a pixel opening exposing at least a portion of an upper surface of the first electrode, a first functional layer disposed in the pixel opening, an inorganic layer disposed in the pixel opening, adjacent to an edge of the pixel opening, and including a crack generation area in which a crack point is defined, an organic protective layer disposed directly on the inorganic layer in the pixel opening and filing the crack point, and a second electrode disposed on the organic protective layer and the pixel defining layer.

This application claims priority to Korean Patent Application No. 10-2024-0198633, filed on Dec. 27, 2024, and all the benefits accruing therefrom under 35 U.S.C. § 119, the content of which in its entirety is herein incorporated by reference.

### BACKGROUND

### 1. Technical Field

Embodiments provide generally to a display device and an electronic device including the same. More particularly, embodiments relate to the display device which provides visual information and the electronic device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

For example, the organic light-emitting display device uses self-luminous light-emitting elements which realize display by emitting light from a light-emitting material including an organic compound. Recently, in order to improve the color reproducibility of the display devices, development is being conducted on light-emitting elements formed from light-emitting materials using quantum dots, and there is a demand for improving the luminous efficiency of the light-emitting elements including quantum dots.

### SUMMARY

Embodiments provide a display device having improved characteristics of a light-emitting element.

Embodiments provide an electronic device including the display device.

A display device according to embodiments of the present disclosure includes first electrode disposed in a light-emitting area on a substrate, a pixel defining layer covering an edge of the first electrode and defining a pixel opening exposing at least a portion of an upper surface of the first electrode, a first functional layer disposed in the pixel opening, an inorganic layer disposed in the pixel opening and including a crack generation area adjacent to edges of the pixel opening and in which a crack point is defined, an organic protective layer disposed directly on the inorganic layer in the pixel opening and filing the crack point, and a second electrode disposed on the organic protective layer and the pixel defining layer.

In an embodiment, an angle between the upper surface of the first electrode covered by the pixel defining layer and a side surface of the pixel defining layer may be in a range of about 50 to about 90 degrees.

In an embodiment, the crack generation area may be an area between a first point of the inorganic layer, which is spaced apart by a first horizontal length in one direction toward a center of the pixel opening from an end of the pixel defining layer contacting the first electrode and a second point of the inorganic layer, which is spaced apart by a second horizontal length in a direction opposite to the one direction from the end of the pixel defining layer, the one direction may be a direction parallel to a major surface of the substrate, and each of the first horizontal length and the second horizontal length may be about 10% or less of a length of the pixel opening in the one direction.

In an embodiment, the crack point may be defined continuously along edges of the pixel opening in the crack generation area in a plan view.

In an embodiment, the inorganic layer may include a light-emitting layer including a plurality of quantum dots and a second functional layer including a plurality of inorganic nanoparticles.

In an embodiment, the organic protective layer may include a central portion corresponding to the center of the pixel opening and a peripheral portion adjacent to the edges of the pixel opening, and a thickness of the central portion may be thinner than a thickness of the peripheral portion.

In an embodiment, the thickness of the central portion of the organic protective layer may be in a range of about 1 to about 120 angstrom (Å).

In an embodiment, the organic protective layer may include a central portion corresponding to the center of the pixel opening and a peripheral portion adjacent to the edges of the pixel opening, and a thickness of the organic protective layer may gradually increase from the central portion to the peripheral portion.

In an embodiment, the organic protective layer may include a material for a soluble process including an organic insulating material.

In an embodiment, in the pixel opening, the first functional layer, the inorganic layer, the organic protective layer, and the second electrode may be disposed in this order on the first electrode along a thickness direction of the display device.

In an embodiment, the first electrode may be an anode electrode and the second electrode may be a cathode electrode.

In an embodiment, the first functional layer may include a hole injection layer and a hole transport layer.

In an embodiment, in the pixel opening, the inorganic layer, the organic protective layer, the first functional layer, and the second electrode may be disposed in this order on the first electrode along a thickness direction of the display device.

In an embodiment, the first electrode may be a cathode electrode and the second electrode may be an anode electrode.

In an embodiment, the first functional layer may include a hole injection layer and a hole transport layer.

An electronic device according to embodiments of the present disclosure includes a display device including: a first electrode disposed in a light-emitting area on a substrate, a pixel defining layer covering an edge of the first electrode and defining a pixel opening exposing at least a portion of an upper surface of the first electrode, a first functional layer disposed in the pixel opening, an inorganic layer disposed in the pixel opening and including a crack generation area adjacent to edges of the pixel opening and in which a crack point is defined, an organic protective layer disposed directly on the inorganic layer in the pixel opening and filing the crack point, and a second electrode disposed on the organic protective layer and the pixel defining layer, and a processor configured to control the display device by providing input image data and a control signal to the display device.

In an embodiment, an angle between the upper surface of the first electrode covered by the pixel defining layer and a side surface of the pixel defining layer may be in a range of about 50 to about 90 degrees.

In an embodiment, the crack generation area may be an area between a first point of the inorganic layer, which is spaced apart by a first horizontal length in one direction toward a center of the pixel opening from an end of the pixel defining layer contacting the first electrode and a second point of the inorganic layer, which is spaced apart by a second horizontal length in a direction opposite to the one direction from the end of the pixel defining layer, the one direction may be a direction parallel to a major surface of the substrate, and each of the first horizontal length and the second horizontal length may be about 10% or less of a length of the pixel opening in the one direction.

In an embodiment, the inorganic layer may include a light-emitting layer including a plurality of quantum dots and a second functional layer including a plurality of inorganic nanoparticles.

In an embodiment, the organic protective layer may include a central portion corresponding to the center of the pixel opening and a peripheral portion adjacent to the edges of the pixel opening, and a thickness of the central portion may be thinner than a thickness of the peripheral portion.

A display device according to embodiments of the present disclosure may include a first electrode disposed in a light-emitting area on a substrate, a pixel defining layer covering an edge of the first electrode and defining a pixel opening exposing at least a portion of an upper surface of the first electrode, a first functional layer disposed in the pixel opening, an inorganic layer disposed in the pixel opening and including a crack generation area adjacent to edges of the pixel opening and in which a crack point is defined, an organic protective layer disposed directly on the inorganic layer in the pixel opening and filing the crack point, and a second electrode disposed on the organic protective layer and the pixel defining layer.

Accordingly, if forming the second electrode, disconnection of the second electrode due to the crack point may be minimized or reduced. In this case, luminance unevenness between pixels may be improved. In addition, by filling the crack point with the organic protective layer, the current may be concentrated in the light-emitting area. In this case, the penetration of the second electrode into the crack point may be effectively minimized or reduced, and thus the leakage current may be effectively reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to embodiments of the present disclosure.

FIG. 2 is a block diagram schematically explaining the display device of FIG. 1.

FIG. 3 is a circuit diagram illustrating a circuit structure of one pixel of FIGS. 1 and 2.

FIG. 4 is a plan view illustrating an enlarged portion of a portion of the display area of FIG. 1.

FIG. 5 is a cross-sectional view illustrating an example of a cross-section taken along line I-I′ of FIG. 4.

FIG. 6 is an enlarged cross-sectional view of area A of FIG. 5.

FIG. 7 is a plan view illustrating a pixel defining layer of FIG. 6.

FIG. 8 is a cross-sectional view illustrating a light-emitting element of FIG. 5.

FIG. 9 is a graph for explaining changes in current density according to embodiments of the present disclosure.

FIG. 10 is a graph for explaining changes in luminous efficiency according to embodiments of the present disclosure.

FIGS. 11, 12, 13, and 14 are cross-sectional views for explaining a method for manufacturing the display device of FIG. 5.

FIG. 15 is a cross-sectional view illustrating another example of a cross-section taken along line I-I′ of FIG. 4.

FIG. 16 is an enlarged cross-sectional view of area B of FIG. 15.

FIG. 17 is a cross-sectional view illustrating a light-emitting element of FIG. 15.

FIG. 18 is a block diagram illustrating an electronic device according to embodiments of the present disclosure.

FIG. 19 is a schematic diagram illustrating an electronic device according to various embodiments.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “substantially equal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially equal” can mean within one or more standard deviations, or within ±10%, 5% or 2% of the stated value.

Hereinafter, a display device and an electronic device including the same according to embodiments of the present disclosure will be explained in detail with reference to the accompanying drawings. The same reference numerals are used for the same components in the drawings, and redundant descriptions of the same components will be omitted.

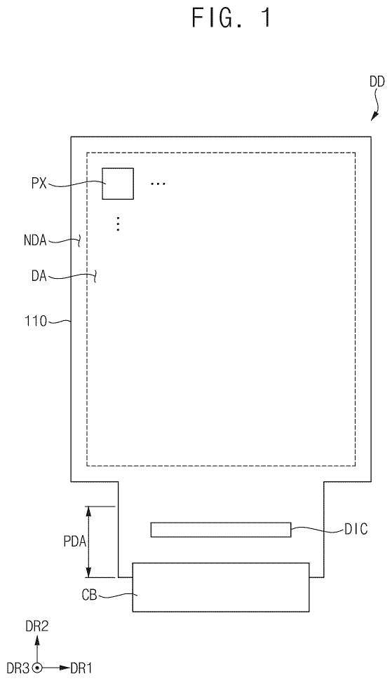

FIG. 1 is a plan view illustrating a display device according to embodiments of the present disclosure. As used herein, the plan view is a view in a thickness direction (i.e., third direction DR3) of the display device.

Referring to FIG. 1, a display device DD according to embodiments of the present disclosure may include a display panel 110, a driving integrated circuit DIC, and a circuit board CB.

The display device DD may have a rectangular planar shape (e.g., a rectangular planar shape with rounded corners). However, the embodiments of the present disclosure are not necessarily limited thereto, and the display device DD may have various planar shapes.

The display panel 110 may include a display area DA and a peripheral area NDA. The display area DA may be an area which generates light or may display an image by controlling the transmittance of light provided from an external light source. The peripheral area NDA may be an area which does not display an image. The peripheral area NDA may be located around the display area DA. For example, the peripheral area NDA may entirely surround the display area DA.

Each of the pixels PX may include a driving element (e.g., a driving thin film transistor) which generates a driving current and a light-emitting element electrically connected to the driving element and which generates light based on the driving current. Accordingly, the pixels PX may emit light according to the driving current. As the pixels PX emit light, the display area DA may display an image.

In the display area DA, lines connected to the pixels PX may be further disposed. For example, the lines may include data lines, gate signal lines, a light-emitting control lines, and/or the like.

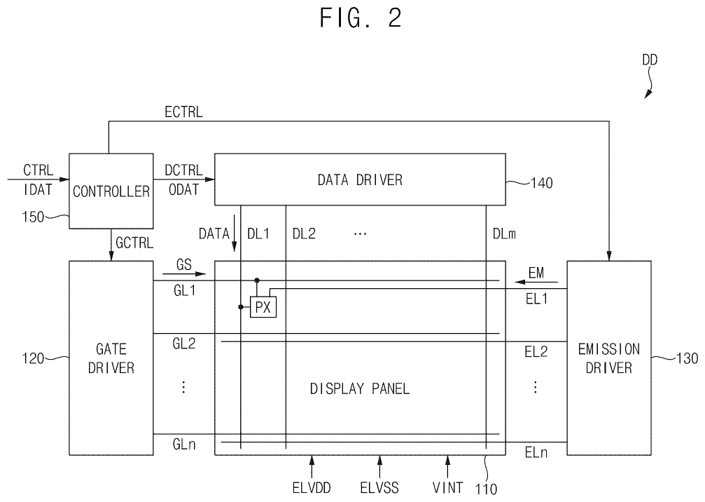

In the peripheral area NDA, drivers for driving the pixels PX may be disposed. For example, the drivers may include a gate driver (e.g., 120 of FIG. 2), an emission driver (e.g., 130 of FIG. 2), a data driver (e.g., 140 of FIG. 2), etc. The pixels PX may emit light based on a signal received from the drivers.

The peripheral area NDA may include a pad area PDA. The pad area PDA may be located at one side of the display area DA. The pad area PDA may extend in the first direction DR1.

The driving integrated circuit DIC may be bonded to the pad area PDA on the display panel 110. Accordingly, the driving integrated circuit DIC may be electrically connected to the display panel 110.

The driving integrated circuit DIC may convert a digital data signal among the driving signals into an analog data signal and provide the analog data signal to the pixels PX. For example, the driving integrated circuit DIC may be the data driver (e.g., 140 of FIG. 2).

The circuit board CB may be bonded to one end of the pad area PDA on the display panel 110. Accordingly, the circuit board CB may be electrically connected to the display panel 110. The other end of the circuit board CB may be electrically connected to an external device. Signals, voltages, and the like generated from the external device may be provided to the driving integrated circuit DIC and the pixels PX through the circuit board CB.

For example, the circuit board CB may be a flexible printed circuit board (FPCB), a printed circuit board (PCB), or a flexible flat cable (FFC).

In FIG. 1, the driving integrated circuit DIC is illustrated as being disposed in a COP (chip on plastic) manner or a COG (chip on glass) manner, but embodiments of the present disclosure are not necessarily limited thereto. For example, the driving integrated circuit DIC may be disposed in a COF (chip on film) manner.

FIG. 2 is a block diagram schematically explaining the display device of FIG. 1.

Referring to FIG. 2, the display device DD according to embodiments of the present disclosure may include the display panel 110, the gate driver 120, the emission driver 130, the data driver 140, and a controller 150.

The display panel 110 may include a plurality of gate signal lines GL1 to GLn, a plurality of data lines DL1 to DLm, a plurality of emission control lines EL1 to ELn, and a plurality of pixels PX (wherein n and m are integers greater than or equal to 2). The gate signal lines GL1 to GLn, the emission control lines EL1 to ELn, and the data lines DL1 to DLm may be electrically connected to the pixels PX. The gate signal lines GL1 to GLn may receive a gate signal GS, the emission control lines EL1 to ELn may receive an emission control signal EM, and the data lines DL1 to DLm may receive a data voltage DATA.

Each of the gate signal lines GL1 to GLn may extend in a first direction (e.g., a row direction). Each of the emission control lines EL1 to ELn may extend in the first direction. Each of the data lines DL1 to DLm may extend in a second direction (e.g., a column direction) intersecting the first direction. The gate signal lines GL1 to GLn, the emission control lines EL1 to ELn, and the data lines DL1 to DLm may be insulated from each other. The pixels PX may be arranged in an area where the gate signal lines GL1 to GLn (or the emission control lines EL1 to ELn) and the data lines DL1 to DLm intersect.

In an embodiment, each of the pixels PX may include a switching transistor which provides the data voltage DATA in response to the gate signal GS, a storage capacitor which stores the data voltage DATA provided by the switching transistor, a driving transistor which generates a driving current based on the data voltage DATA stored in the storage capacitor, and a light-emitting element which emits light based on the driving current generated by the driving transistor. For example, the light-emitting element may include a light-emitting diode LED, an organic light-emitting diode (OLED), or a quantum dot (QD) light-emitting element.

The pixels PX may receive a driving voltage ELVDD and a common voltage ELVSS. The pixels PX may receive the data voltage DATA in response to the gate signal GS and the emission control signal EM, and may generate light having a grayscale corresponding to the data voltage DATA by using the driving voltage ELVDD and the common voltage ELVSS. In addition, the pixels PX may receive an initialization voltage VINT.

The gate driver 120 may provide the gate signals GS to the pixels PX through the gate signal lines GL1 to GLn based on a gate control signal GCTRL received from the controller 150. In an embodiment, the gate driver 120 may sequentially provide the gate signals GS to the pixels PX in units of rows. In addition, the gate control signal GCTRL may include a gate start signal, a gate clock signal, and/or the like, but embodiments of the present disclosure are not necessarily limited thereto. For example, the gate driver 120 may be integrated or formed in a peripheral portion of the display panel 110. Alternatively, the gate driver 120 may be implemented with one or more integrated circuits IC.

The emission driver 130 may provide the emission control signals EM to the pixels PX through the emission control lines EL1 to ELn based on an emission control signal ECTRL received from the controller 150. In an embodiment, the emission driver 130 may sequentially provide the emission control signals EM to the pixels PX in units of rows. In addition, the emission control signal ECTRL may include a light emitting start signal, a light emitting clock signal, and/or the like, but the embodiments of the present disclosure are not necessarily limited thereto. For example, the emission driver 130 may be integrated or formed in a peripheral portion of the display panel 110. Alternatively, the emission driver 130 may be implemented with one or more integrated circuits IC.

The data driver 140 may receive a data control signal DCTRL and an output image data ODAT from the controller 150, and provide the data voltages DATA to the pixels PX through the data lines D1L to DLm based on the data control signal DCTRL and the output image data ODAT. In addition, the data control signal DCTRL may include an output data enable signal, a horizontal start signal, a load signal, and/or the like, but embodiments of the present disclosure are not necessarily limited thereto. For example, the data driver 140 may be implemented as a single integrated circuit, and the integrated circuit may be referred to as a timing controller embedded data driver (TED). Alternatively, the data driver 140 may be implemented as separate integrated circuits.

The controller 150 may receive an input image data IDAT and a control signal CTRL from an external host processor. For example, the controller 150 may be a timing controller, and the host processor may include at least one of a central processing unit (CPU), an application processor (AP), a graphic processing unit (GPU), a communication processor (CP), and an image signal processor (ISP). In an embodiment, the input image data IDAT may be RGB image data including red image data, green image data, and blue image data. In addition, the control signal CTRL may include a vertical synchronization signal, a horizontal synchronization signal, an input data enable signal, a master clock signal, and/or the like, but embodiments of the present disclosure are not necessarily limited thereto.

The controller 150 may generate the gate control signal GCTRL, the emission control signal ECTRL, the data control signal DCTRL, and the output image data ODAT based on the input image data IDAT and the control signal CTRL. The controller 150 may control the operation of the gate driver 120 by providing the gate control signal GCTRL to the gate driver 120. The controller 150 may control the operation of the emission driver 130 by providing the emission control signal ECTRL to the emission driver 130. In addition, the controller 150 may control the operation of the data driver 140 by providing the output image data ODAT and the data control signal DCTRL to the data driver 140. That is, the controller 150 may control the operation of the display panel 110 based on the input image data IDAT and the control signal CTRL.

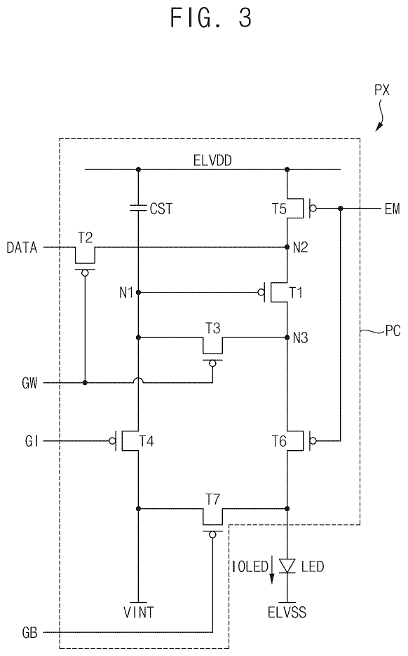

FIG. 3 is a circuit diagram illustrating a circuit structure of one pixel of FIGS. 1 and 2.

Referring to FIG. 3, each pixel PX may include a pixel driving circuit part PC and a light-emitting element LED electrically connected to the pixel driving circuit part PC. The pixel driving circuit part PC may generate a driving current IOLED, and the light-emitting element LED may generate light based on the driving current IOLED.

In an embodiment, the pixel driving circuit part PC may include a first transistor T1, a second transistor T2, a third transistor T3, a fourth transistor T4, a fifth transistor T5, a sixth transistor T6, a seventh transistor T7, and a storage capacitor CST.

In an embodiment, the first transistor T1, the second transistor T2, the third transistor T3, the fourth transistor T4, the fifth transistor T5, the sixth transistor T6, and the seventh transistor T7 may all be PMOS transistors. However, the embodiments of the present disclosure are not necessarily limited thereto, and some of the first transistor T1, the second transistor T2, the third transistor T3, the fourth transistor T4, the fifth transistor T5, the sixth transistor T6, and the seventh transistor T7 may be PMOS transistors, and the rest may be NMOS transistors.

If the pixel driving circuit part PC includes an NMOS transistor and a PMOS transistor, an active pattern of the NMOS transistor may include an oxide semiconductor, and an active pattern of the PMOS transistor may include a silicon semiconductor. However, the embodiments of the present disclosure are not necessarily limited thereto, and the active pattern of the NMOS transistor may include a silicon semiconductor, and the active pattern of the PMOS transistor may include an oxide semiconductor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide the driving current IOLED to the light-emitting element LED.

The second transistor T2 may include a gate electrode, a first electrode, and a second electrode. A first gate signal GW may be applied to the gate electrode of the second transistor T2. The data voltage DATA may be applied to the first electrode of the second transistor T2. The second electrode of the second transistor T2 may be connected to the second node N2.

The second transistor T2 may be turned on or off in response to the first gate signal GW. For example, if the first gate signal GW has an activation level, the second transistor T2 may be turned on. In this case, the second transistor T2 may provide the data voltage DATA to the second node N2. Conversely, if the first gate signal GW has an inactivation level, the second transistor T2 may be turned off. In this case, the second transistor T2 may block the supply of the data voltage DATA.

The third transistor T3 may include a gate electrode, a first electrode, and a second electrode. The first gate signal GW may be applied to the gate electrode of the third transistor T3. The first electrode of the third transistor T3 may be connected between the first node N1 and the fourth transistor T4. The second electrode of the third transistor T3 may be connected to the third node N3.

The third transistor T3 may be turned on or off in response to the first gate signal GW. For example, if the first gate signal GW has an activation level, the third transistor T3 may be turned on. In this case, the third transistor T3 may diode-connect the first transistor T1. That is, the third transistor T3 may compensate for the threshold voltage of the first transistor T1. Conversely, if the second gate signal GC has an inactivation level, the third transistor T3 may be turned off. In this case, the third transistor T3 may be turned off. In this case, the first transistor T1 may not be diode-connected.

The fourth transistor T4 may include a gate electrode, a first electrode, and a second electrode. A second gate signal GI may be applied to the gate electrode of the fourth transistor T4. The initialization voltage VINT may be applied to the first electrode of the fourth transistor T4. The second electrode of the fourth transistor T4 may be connected to the first electrode of the third transistor T3.

The fourth transistor T4 may be turned on or off in response to the second gate signal GI. For example, if the second gate signal GI has an activation level, the fourth transistor T4 may be turned on. In this case, the fourth transistor T4 may provide the initialization voltage VINT to the first node N1. Conversely, if the second gate signal GI has an inactivation level, the fourth transistor T4 may block the supply of the initialization voltage VINT.

The fifth transistor T5 may include a gate electrode, a first electrode, and a second electrode. The emission control signal EM may be applied to the gate electrode of the fifth transistor T5. The driving voltage ELVDD may be applied to the first electrode of the fifth transistor T5. The second electrode of the fifth transistor T5 may be connected to the second node N2.

The sixth transistor T6 may include a gate electrode, a first electrode, and a second electrode. The emission control signal EM may be applied to the gate electrode of the sixth transistor T6. The first electrode of the sixth transistor T6 may be connected to the third node N3. The second electrode of the sixth transistor T6 may be connected to a second electrode of the seventh transistor T7.

The fifth transistor T5 and the sixth transistor T6 may be turned on or off in response to the emission control signal EM. For example, if the emission control signal EM has an activation level, the fifth transistor T5 and the sixth transistor T6 may be turned on. In this case, the fifth transistor T5 and the sixth transistor T6 may provide the driving current IOLED generated by the first transistor T1 to the anode electrode of the light-emitting element LED. Conversely, if the emission control signal EM has an inactivation level, the fifth transistor T5 and the sixth transistor T6 may block the supply of the driving current IOLED generated from the first transistor T1.

The seventh transistor T7 may include a gate electrode, a first electrode, and a second electrode. A third gate signal GB may be applied to the gate electrode of the seventh transistor T7. The initialization voltage VINT may be applied to the first electrode of the seventh transistor T7. The second electrode of the seventh transistor T7 may be connected to the second electrode of the sixth transistor T6.

The seventh transistor T7 may be turned on or off in response to the third gate signal GB. For example, if the third gate signal GB has an activation level, the seventh transistor T7 may be turned on. In this case, the seventh transistor T7 may provide the initialization voltage VINT to the anode electrode of the light-emitting element LED. Conversely, if the third gate signal GB has an inactivation level, the seventh transistor T7 may block the supply of the initialization voltage VINT.

In an embodiment, the first electrode of each of the first, second, third, fourth, fifth, sixth, and seventh transistors T1, T2, T3, T4, T5, T6, and T7 may be a source electrode, and the second electrode of each of the first, second, third, fourth, fifth, sixth, and seventh transistors T1, T2, T3, T4, T5, T6, and T7 may be a drain electrode. However, the embodiments of the present disclosure are not necessarily limited thereto, and the first electrode of at least one of the first electrode of each of the first, second, third, fourth, fifth, sixth, and seventh transistors T1, T2, T3, T4, T5, T6, and T7 may be a source electrode, and the second electrode of the remaining of the first, second, third, fourth, fifth, sixth, and seventh transistors T1, T2, T3, T4, T5, T6, and T7 may be a drain electrode.

The storage capacitor CST may include a first electrode and a second electrode. The driving voltage ELVDD may be applied to the first electrode of the storage capacitor CST. The second electrode of the storage capacitor CST may be connected to the first node N1.

The light-emitting element LED may include the anode electrode and the cathode electrode. The anode electrode of the light-emitting element LED may be connected to the second electrode of the sixth transistor T6 and the second electrode of the seventh transistor T7. The common voltage ELVSS may be applied to the cathode electrode of the light-emitting element LED. The common voltage ELVSS may have a voltage level lower than the driving voltage ELVDD.

Although FIG. 3 illustrates that one pixel driving circuit part PC includes seven transistors and one capacitor, embodiments of the present disclosure are not necessarily limited thereto.

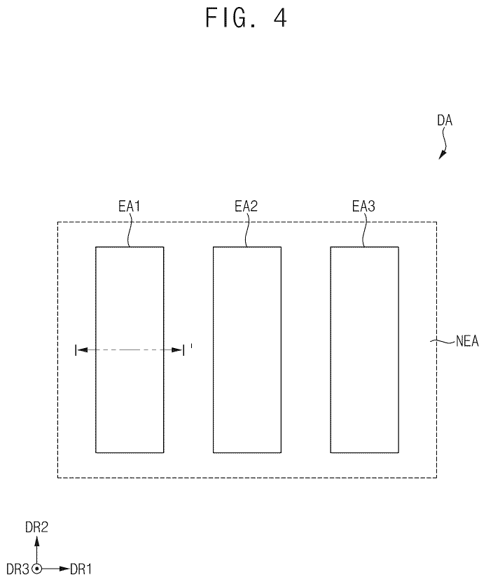

FIG. 4 is a plan view illustrating an enlarged portion of a portion of the display area of FIG. 1.

Referring to FIG. 4, the display area DA may include a first light-emitting area EA1, a second light-emitting area EA2, a third light-emitting area EA3, and a non-light-emitting area NEA. For example, the first light-emitting area EA1 may emit light of a first color, the second light-emitting area EA2 may emit light of a second color, and the third light-emitting area EA3 may emit light of a third color. In an embodiment, the first color may be red, the second color may be green, and the third color may be blue, but the embodiments of the present disclosure are not necessarily limited thereto. The plurality of pixels PX are elements which emit light, and one pixel PX may be disposed in each of the first, second, and third light-emitting areas EA1, EA2, and EA3.

The non-light-emitting area NEA may surround the first, second, and third light-emitting areas EA1, EA2, and EA3 in a plan view. The non-light-emitting area NEA may be an area which does not emit light.

The first, second, and third light-emitting areas EA1, EA2, and EA3 may be arranged in a matrix shape along the first direction DR1 and the second direction DR2. In an embodiment, the first, second, and third light-emitting areas EA1, EA2, and EA3 may be arranged in a PentileTM shape. However, the embodiments of the present disclosure are not necessarily limited thereto.

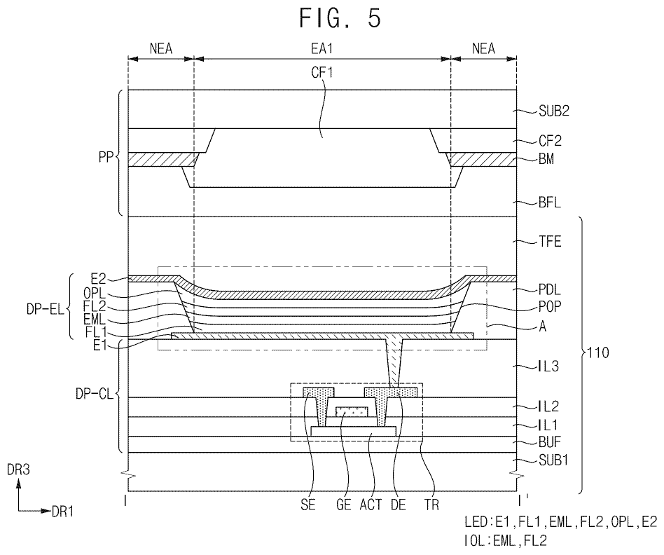

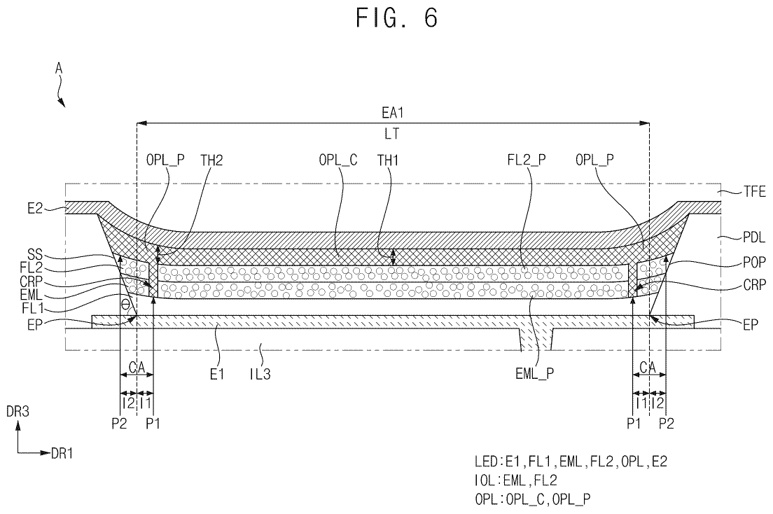

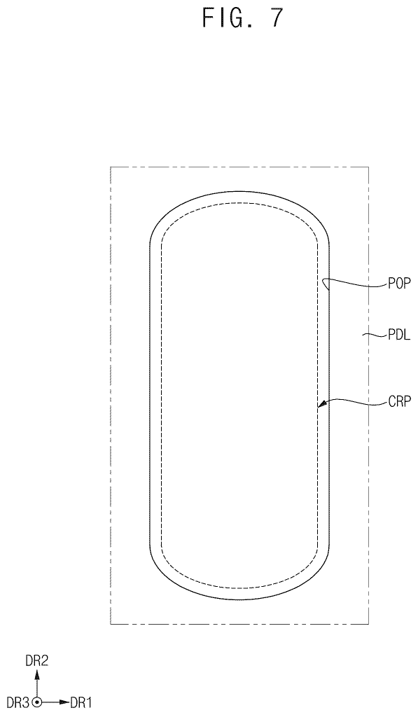

FIG. 5 is a cross-sectional view illustrating an example of a cross-section taken along line I-I′ of FIG. 4. FIG. 6 is an enlarged cross-sectional view of area A of FIG. 5. FIG. 7 is a plan view illustrating a pixel defining layer of FIG. 6.

For example, FIG. 5 is a cross-sectional view illustrating the first light-emitting area EA1 of FIG. 4. A cross-sectional structure of the first light-emitting area EA1 of FIG. 5, which will be described later, may be substantially equally applied to the second light-emitting area EA2 and the third light-emitting area EA3 of FIG. 4.

Referring to FIGS. 1 and 5, the display device DD may further include an optical member PP disposed on the display panel 110. The display panel 110 may include a first substrate SUB1, a circuit layer DP-CL, a light-emitting element layer DP-EL, and an encapsulation layer TFE. The circuit layer DP-CL may include a buffer layer BUF, a transistor TR, and first, second, and third insulating layers IL1, IL2, and IL3. The light-emitting element layer DP-EL may include a pixel defining layer PDL and a light-emitting element LED. In addition, the optical member PP may include a second substrate SUB2, first and second color filters CF1 and CF2, a light-blocking layer BM, and a protective layer BFL.

Here, the transistor TR may include an active pattern ACT, a gate electrode GE, a source electrode SE, and a drain electrode DE, and the light-emitting element LED may include a first electrode E1, a first functional layer FL1, a light-emitting layer EML, a second functional layer FL2, and a second electrode E2.

The first substrate SUB1 may include a glass substrate, a metal substrate, a plastic substrate, or the like. However, the embodiments of the present disclosure are not necessarily limited thereto. For example, the first substrate SUB1 may include an inorganic layer, an organic layer, or a composite material layer. In addition, the first substrate SUB1 may include a flexible substrate having flexibility.

The buffer layer BUF may be disposed on the first substrate SUB1. The buffer layer BUF may prevent metal atoms or impurities from diffusing from the first substrate SUB1 to the transistor TR. In addition, the buffer layer BUF may improve the flatness of the surface of the first substrate SUB1 if the surface of the first substrate SUB1 is not uniform. For example, the buffer layer BUF may include an inorganic material such as silicon oxide (SiOx), silicon nitride (SiNx), silicon oxynitride (SiOxNy), and the like. These may be used alone or in combination with each other.

The active pattern ACT may be disposed on the buffer layer BUF. The active pattern ACT may include a metal oxide semiconductor, an inorganic semiconductor (e.g., amorphous silicon, polysilicon), or an organic semiconductor. For example, the metal oxide semiconductor may include zinc oxide (e.g., ZnO or ZnO2), gallium oxide (GaOx), tin oxide (SnOx), indium oxide (InOx), indium gallium oxide (IGO), indium zinc oxide (IZO), indium tin oxide (ITO), indium zinc tin oxide (IZTO), indium gallium zinc oxide (IGZO), and/or the like. These may be used alone or in combination with each other.

The active pattern ACT may include a source region, a drain region, and a channel region located between the source region and the drain region. Each of the source region and the drain region may be a region doped with an impurity (e.g., an n-type impurity or a p-type impurity), and the channel region may be a region not doped with an impurity.

The first insulating layer IL1 may be disposed on the buffer layer BUF. The first insulating layer IL1 may sufficiently cover the active pattern ACT and may have a substantially flat upper surface without forming a step around the active pattern ACT. Alternatively, the first insulating layer IL1 may cover the active pattern ACT and may be disposed along the profile of the active pattern ACT with a uniform thickness. For example, the first insulating layer IL1 may include an inorganic material such as silicon oxide (SiOx), silicon nitride (SiNₓ), silicon oxynitride (SiOₓN_{y}), or the like. These may be used alone or in combination with each other.

The gate electrode GE may be disposed on the first insulating layer IL1. The gate electrode GE may overlap the channel region of the active pattern ACT in the plan view. The gate electrode GE may include a metal, an alloy metal nitride, a conductive metal oxide, a transparent conductive material, and/or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. Examples of the conductive metal oxide may include indium tin oxide, indium zinc oxide, and the like. In addition, examples of the metal nitride may include aluminum nitride (AlNₓ), tungsten nitride (WNₓ), chromium nitride (CrNₓ), and the like. These may be used alone or in combination with each other.

The second insulating layer IL2 may be disposed on the first insulating layer IL1. The second insulating layer IL2 may sufficiently cover the gate electrode GE and may have a substantially flat upper surface without forming a step around the gate electrode GE. Alternatively, the second insulating layer IL2 may cover the gate electrode GE and may be disposed along the profile of the gate electrode GE with a uniform thickness. For example, the second insulating layer IL2 may include an inorganic material such as silicon oxide, silicon nitride, silicon oxynitride, and/or the like. These may be used alone or in combination with each other.

The source electrode SE and the drain electrode DE may be disposed on the second insulating layer IL2. The source electrode SE may be connected to the source region of the active pattern ACT through a contact hole penetrating the first and second insulating layers IL1 and IL2. The drain electrode DE may be connected to the drain region of the active pattern ACT through a contact hole penetrating the first and second insulating layers IL1 and IL2. For example, each of the source electrode SE and the drain electrode DE may include a metal, an alloy, a metal nitride, a conductive metal oxide, a transparent conductive material, and/or the like. These may be used alone or in combination with each other.

The third insulating layer IL3 may be disposed on the second insulating layer IL2. The third insulating layer IL3 may sufficiently cover the source electrode SE and the drain electrode DE. That is, the third insulating layer IL3 may be a planarization layer. The third insulating layer IL3 may include an organic material. For example, the third insulating layer IL3 may include an organic material such as a photoresist, a polyacrylic resin, a polyimide resin, a polyamide resin, a siloxane resin, an acrylic resin, an epoxy resin, and the like. These may be used alone or in combination with each other.

The first electrode E1 may be disposed on the third insulating layer IL3. The first electrode E1 may overlap the first light-emitting area EA1 in a plan view. The first electrode E1 may be connected to the drain electrode DE (or, the source electrode SE) through a contact hole penetrating the third insulating layer IL3. The first electrode E1 may be a transmissive electrode, a semi-transmissive electrode, or a reflective electrode. For example, the first electrode E1 may include a metal, an alloy, a metal nitride, a conductive metal oxide, a transparent conductive material, and/or the like. These may be used alone or in combination with each other. In an embodiment, the first electrode E1 may be an anode electrode.

For example, the first electrode E1 may be patterned to correspond to each of the first, second, and third light-emitting areas EA1, EA2, and EA3 illustrated in FIG. 4. Alternatively, the first electrode E1 may be integrally formed over the first, second, and third light-emitting areas EA1, EA2, and EA3 and the non-light-emitting area NEA illustrated in FIG. 4 provided as a single common layer.

The pixel defining layer PDL may be disposed on the third insulating layer IL3. The pixel defining layer PDL may overlap the non-emitting area NEA. A pixel opening POP exposing at least a portion of the upper surface of each of the first electrodes E1 may be defined in the pixel defining layer PDL. The pixel defining layer PDL may include an inorganic material and/or an organic material. For example, the pixel defining layer PDL may include an organic material such as a photoresist, a polyacrylic resin, a polyimide resin, a polyamide resin, a siloxane resin, an acrylic resin, an epoxy resin, and/or the like. These may be used alone or in combination with each other. Alternatively, the pixel defining layer PDL may include an inorganic material and/or an organic material containing a light-blocking material such as a black pigment, a black dye, and the like.

The first functional layer FL1 may be disposed on the first electrode E1. The first functional layer FL1 may overlap the first light-emitting area EA1. Specifically, the first functional layer FL1 may be arranged in the pixel opening POP of the pixel defining film PDL.

The components of the first functional layer FL1 will be described by taking as an example the case where the first electrode E1 is an anode electrode and the second electrode E2 is a cathode electrode.

The first functional layer FL1 may include a hole transport layer. The hole transport layer may play a role in facilitating the injection of holes from the first electrode E1 to the light-emitting layer EML.

In an embodiment, the hole transport layer may include a material for a solution process. For example, the material for the solution process of the hole transport layer may include a hole transport material such as carbazole-based derivatives such as N-phenylcarbazole and polyvinylcarbazole, fluorene-based derivatives, triphenylamine-based derivatives such as TPD (N,N′-bis(3-methylphenyl)-N,N′-diphenyl-[1,1′-biphenyl]-4,4′-diamine) and TCTA (4,4′,4″-tris(N-carbazolyl)triphenylamine), NPD (N,N′-di(naphthalene-1-yl)-N,N′-diphenyl-benzidine), TAPC (4,4′-cyclohexylidenebis[N, N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), and the like. These may be used alone or in combination with each other. However, the embodiments of the present disclosure are not necessarily limited thereto.

The first functional layer FL1 may further include a hole injection layer in addition to the hole transport layer. In this case, the hole injection layer may be disposed between the first electrode E1 and the hole injection layer. The hole injection layer may improve hole injection characteristics into the hole transport layer without increasing the driving voltage. In an embodiment, the hole injection layer may include a material for a solution process. For example, the material for the solution process of the hole injection layer may include a general hole injection material known in the art.

For example, the first functional layer FL1 may be patterned to correspond to each of the first, second, and third light-emitting areas EA1, EA2, and EA3 illustrated in FIG. 4. Alternatively, the first functional layer FL1 may be integrally formed over the first, second, and third light-emitting areas EA1, EA2, and EA3 and the non-light-emitting area NEA illustrated in FIG. 4 provided as a single common layer.

The light-emitting layer EML may be disposed on the first functional layer FL1. The light-emitting layer EML may overlap the first light-emitting area EA1. Specifically, the light-emitting layer EML may be disposed in the pixel opening POP of the pixel defining layer PDL.

The light-emitting layer EML may include a material for a solution process. In an embodiment, the material for the solution process of the light-emitting layer EML may include a light-emitting material such as a plurality of quantum dots EML_P. For example, the quantum dots EML_P may emit light of a specific color (e.g., red).

For example, each of the quantum dots EML_P may have a core-shell structure including a core and a shell surrounding the core. The shell may serve as a protective layer to prevent chemical modification of the core and maintain semiconductor properties, and may serve as a charging layer to impart electrophoretic properties to the quantum dots EML_P.

For example, the core of each of the quantum dots EML_P may include a group II-VI compound, a group III-V compound, a group IV-VI compound, a group IV element, a group IV compound, and/or the like. These may be used alone or in combination with each other.

For example, the group II-VI compound may include binary compounds such as CdSe, CdTe, CdS, ZnS, ZnSe, ZnTe, ZnO, HgS, HgSe, HgTe, MgSe, MgS, and the like; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; and quaternary compounds such as HgZnTeS, CdZnSeS, CdZnSeTe, CdZnSTe, CdHgSeS, CdHgSeTe, CdHgSTe, HgZnSeS, HgZnSeTe, and the like. These may be used alone or in combination with each other. In addition, the group II-VI compound may further include a group I metal and/or a group IV element.

For example, the group III-V compound may include binary compounds such as GaS, Ga₂S₃, GaSe, Ga₂Se₃, GaTe, InTe, InS, InSe, In₂S₃, In₂Se₃, and the like, and ternary compounds such as InGaS₃, InGaSe₃, and the like. These may be used alone or in combination with each other.

For example, the group IV-VI compound may include binary compounds such as SnS, SnSe, SnTe, PbS, PbSe, PbTe, and the like; ternary compounds such as SnSeS, SnSeTe, SnSTe, PbSeS, PbSeTe, PbSTe, SnPbS, SnPbSe, SnPbTe, and the like; and quaternary compounds such as SnPbSSe, SnPbSeTe, SnPbSTe, and the like. The group IV element may include Si, Ge, and/or the like. The group IV compound may include SiC, SiGe, and/or the like. These may be used alone or in combination with each other.

In an embodiment, the material included in the core and the material included in the shell may be different from each other. The shell of the quantum dot may include a metal or non-metal oxide, a semiconductor compound, or the like.

For example, the oxide of the metal or non-metal may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, or ternary compounds such as MgAl₂O₄, CoFe₂O₄, NiFe₂O₄, CoMn₂O₄, and the like. These may be used alone or in combination with each other.

For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like. These may be used alone or in combination with each other.

The second functional layer FL2 may be disposed on the light-emitting layer EML. The second functional layer FL2 may overlap the first light-emitting area EA1. Specifically, the second functional layer FL2 may be disposed in the pixel opening POP of the pixel defining layer PDL.

The components of the second functional layer FL2 will be described by taking as an example the case where the first electrode E1 is an anode electrode and the second electrode E2 is a cathode electrode.

The second functional layer FL2 may include an electron transport layer. The electron transport layer may transport electrons from the second electrode E2 to the light-emitting layer EML.

The electron transport layer may include a material for a solution process. In an embodiment, the material for the solution process of the electron transport layer may include an electron transport material such as a plurality of inorganic nanoparticles FL2_P. The inorganic nanoparticles FL2_P may serve to transport electrons injected from the second electrode E2.

The inorganic nanoparticles FL2_P may include a metal oxide. For example, the metal oxide may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, Y₂O₃, and the like, or ternary compounds such as ZnMgO, MgAl₂O₄, CoFe₂O₄, NiFe₂O₄, CoMn₂O₄, BaTiO₃, BaZrO₃, ZrSiO₄, and the like. These may be used alone or in combination with each other. In an embodiment, the inorganic nanoparticles FL2_P may include ZnO, ZnMgO, and/or the like.

For example, the second functional layer FL2 may be patterned to correspond to each of the first, second, and third light-emitting areas EA1, EA2, and EA3 illustrated in FIG. 4. Alternatively, the second functional layer FL2 may be integrally formed over the first, second, and third light-emitting areas EA1, EA2, and EA3 and the non-light-emitting area NEA illustrated in FIG. 4 provided as a single common layer.

In FIGS. 5 and 6, the light-emitting layer EML and the second functional layer FL2 may be collectively defined as an inorganic layer IOL. That is, the inorganic layer IOL may include the light-emitting layer EML and the second functional layer FL2.

In an embodiment, an angle θ between a side surface SS of the pixel defining layer PDL and the upper surface of the first electrode E1 covered by the pixel defining layer PDL may be in a range of about 50 to about 90 degrees. Preferably, the angle θ between the side surface SS of the pixel defining layer PDL and the upper surface of the first electrode E1 covered by the pixel defining layer PDL may be in a range of about 55 to about 90 degrees. If the angle θ between the side surface SS of the pixel defining layer PDL and the upper surface of the first electrode E1 covered by the pixel defining layer PDL is in a range of about 50 to about 90 degrees, an aperture ratio of the pixel opening POP may be relatively large. In this case, the luminous efficiency of the display device DD may be improved, and this may be advantageous for high-resolution implementation of the display device DD.

However, if the angle θ between the side surface SS of the pixel defining layer PDL and the upper surface of the first electrode E1 covered by the pixel defining layer PDL is in a range of about 50 to about 90 degrees, a crack point CRP may be formed (or defined) in the inorganic layer IOL in a crack generation area CA adjacent to an edge of the pixel opening POP after a drying and baking process for removing a solvent in the inorganic layer IOL. In this case, if the second electrode E2 is formed directly on the inorganic layer IOL, the second electrode E2 may be disconnected due to the crack point CRP. In addition, if the second electrode E2 is formed directly on the inorganic layer IOL, the second electrode E2 may penetrate into the crack point CRP, which may increase leakage current. If the second electrode E2 is disconnected, luminance unevenness between the pixels may occur, and if the leakage current increases, the performance of the display panel 110 may deteriorate.

For example, as illustrated in FIG. 7, the crack point CRP may be defined continuously along the edge of the pixel opening POP in the crack generation area CA. However, the embodiments of the present disclosure are not necessarily limited thereto.

The crack generation area CA may be an area between a first point P1 of the inorganic layer IOL, which is spaced apart by a first horizontal length I1 in one direction toward a center of the pixel opening POP from an end EP of the pixel defining layer PDL contacting the first electrode E1 and a second point P2 of the inorganic layer IOL, which is spaced apart by a second horizontal length I2 in a direction opposite to the one direction from the end EP of the pixel defining layer PDL. Here, the one direction may be a direction parallel to the major surface of the first substrate SUB1 defined by the first and second directions DR1 and DR2. In an embodiment, each of the first horizontal length I1 and the second horizontal length I2 may be about 10% or less of a length LT of the pixel opening POP in the first direction DR1.

In an embodiment, the light-emitting element LED may further include an organic protective layer OPL disposed directly on the inorganic layer IOL in the pixel opening POP and filling the crack point CRP. That is, the first functional layer FL1, the inorganic layer IOL, the organic protective layer OPL, and the second electrode E2 may be disposed in this order along a thickness direction (i.e., the third direction DR3) on the first electrode E1 in the pixel opening POP. Accordingly, if forming the second electrode E2, the disconnection of the second electrode E2 due to the crack point CRP may be minimized or reduced. In this case, the luminance unevenness between the pixels may be improved. In addition, since the organic protective layer OPL is filled in the crack point CRP, the current may be concentrated on the first light-emitting area EA1. In this case, the penetration of the second electrode E2 into the crack point CRP may be minimized or reduced, and thus the leakage current may be effectively reduced.

The organic protective layer OPL may include a center portion OPL_C corresponding to the center of the pixel opening POP and a peripheral portion OPL_P adjacent to an edge of the pixel opening POP. In an embodiment, a thickness TH1 and TH2 of the organic protective layer OPL may gradually increase from the center portion OPL_C to the peripheral portion OPL_P. That is, the first thickness TH1 of the central portion OPL_C of the organic protective layer OPL may be thinner than the second thickness TH2 of the peripheral portion OPL_P. The second thickness TH2 of the peripheral portion OPL_P of the organic protective layer OPL must be relatively thick so that the organic protective layer OPL may sufficiently fill the crack point CRP. In addition, the first thickness TH1 of the central portion OPL_C of the organic protective layer OPL may not be deteriorated so that the characteristics of the light-emitting element LED are not deteriorated.

If forming the organic protective layer OPL, by appropriately changing the number of drops of the material for the solution process and/or the drying conditions, the organic protective layer OPL may be formed such that the thickness TH1 and TH2 of the organic protective layer OPL increases from the center portion OPL_C to the peripheral portion OPL_P.

In an embodiment, the first thickness TH1 of the central portion OPL_C of the organic protective layer OPL may be in a range of about 1 about 120 angstrom (Å). If the first thickness TH1 of the central portion OPL_C of the organic protective layer OPL is less than about 1 angstrom (Å), an overall thickness of the organic protective layer OPL may also be relatively thin. In this case, the organic protective layer OPL may not be sufficiently filled in the crack point CRP. If the first thickness TH1 of the center portion OPL_C of the organic protective layer OPL exceeds about 120 angstrom (Å), current may not flow well in the light-emitting element LED.

In an embodiment, the organic protective layer OPL may include a material for the solution process including an organic insulating material. For example, the organic insulating material may include poly(ethylene glycol), poly(4-vinylpyridine), polyvinylpyrrolidone, polyethyleneimine, and/or the like. These may be used alone or in combination with each other. Alternatively, the organic protective layer OPL may include an organic semiconductor instead of the organic insulating material.

In an embodiment, the material for the solution process of the organic protective layer OPL may further include an electron injection material. In this case, the organic protective layer OPL may also function as an electron injection layer. The electron injection layer may improve electron injection characteristics into the electron transport layer without increasing the driving voltage. For example, the electron injection material may include a general material known in the art.

In this specification, the material for the solution process denotes all materials used to form one specific layer of the light-emitting element LED excluding the first electrode E1 and the second electrode E2 by the solution process, and the material for the solution process may include functional materials (e.g., hole transport materials, hole injection materials, light-emitting materials, electron transport materials, and the like) and auxiliary materials (e.g., solvents, additives, and the like)

For example, the solution process may include an inkjet printing process, a screen-printing process, a spray coating process, or the like. However, the embodiments of the present disclosure are not necessarily limited thereto.

The second electrode E2 may be disposed on the organic protective layer OPL and the pixel defining layer PDL. The second electrode E2 may be a transmissive electrode, a semi-transmissive electrode, or a reflective electrode. For example, the second electrode E2 may include a metal, an alloy, a metal nitride, a conductive metal oxide, a transparent conductive material, and/or the like. These may be used alone or in combination with each other. In an embodiment, the second electrode E2 may be a cathode electrode.

For example, the second electrode E2 may be formed integrally and provided as a single common layer. That is, the second electrode E2 may be commonly disposed in the first, second, and third light-emitting areas EA1, EA2, and EA3 and the non-light-emitting area NEA of FIG. 4.

The encapsulation layer TFE may be disposed on the second electrode E2. The encapsulation layer TFE may be commonly disposed in the first, second, and third light-emitting areas EA1, EA2, and EA3 and the non-light-emitting area NEA of FIG. 4.

The encapsulation layer TFE may cover the light-emitting element LED. The encapsulation layer TFE may include at least one inorganic layer and at least one organic layer. The inorganic layer of the encapsulation layer TFE may protect the light-emitting element LED from external moisture, and the organic layer of the encapsulation layer TFE may prevent the light-emitting element LED from being stamped due to foreign substances introduced during the manufacturing process.

For example, the encapsulation layer TFE may include a first inorganic encapsulation layer, a second inorganic encapsulation layer disposed on the first inorganic encapsulation layer, and an organic encapsulation layer disposed between the first inorganic encapsulation layer and the second inorganic encapsulation layer.

The optical member PP may be disposed on the encapsulation layer TFE. The optical member PP may block external light provided from the outside of the display panel 110 to the display panel 110. That is, the optical member PP may perform an anti-reflection function which minimizes reflection by external light. Hereinafter, the components of the optical member PP will be described.

The second substrate SUB2 may include a glass substrate, a metal substrate, a plastic substrate, or the like. In an embodiment, the second substrate SUB2 may include a glass substrate. However, the embodiments of the present invention are not necessarily limited thereto. For example, the second substrate SUB2 may include an inorganic layer, an organic layer, or a composite material layer. The second substrate SUB2 may be a encapsulation substrate.

A sealant may be disposed between the first substrate SUB1 and the second substrate SUB2. The sealant may be disposed in the peripheral area NDA of FIG. 1. The sealant may surround the display area DA of FIG. 1 and prevent moisture from penetrating through a side surface.

The first and second color filters CF1 and CF2 may be disposed under the second substrate SUB2. The first and second color filters CF1 and CF2 may selectively transmit light of a specific wavelength.

The first color filter CF1 may overlap the first light-emitting area EA1. The first color filter CF1 may transmit light of the first color (e.g., red light). For example, the first color filter CF1 may include a red pigment or a red dye.

The second color filter CF2 may overlap the non-emitting area NEA and the third emitting area EA3 of FIG. 4. The second color filter CF2 may transmit light of the third color (e.g., blue light). For example, the second color filter CF2 may include a blue pigment or a blue dye. However, the embodiments of the present disclosure are not necessarily limited thereto.

For example, the second color filter CF2 may partially overlap the first color filter CF1 in the plan view. However, embodiments of the present disclosure are not necessarily limited thereto, and the first and second color filters CF1 and CF2 may not overlap each other in a plan view. In this case, three color filters may be disposed to correspond to the first, second, and third light-emitting areas EA1, EA2, and EA3 of FIG. 4, respectively.

The light-blocking layer BM may be disposed under the first and second color filters CF1 and CF2. The light-blocking layer BM may overlap the non-light emitting area NEA. The light-blocking layer BM may be a black matrix. For example, the light-blocking layer BM may include an organic light-shielding material or an inorganic light-shielding material containing a black pigment or a black dye. The light-blocking layer BM may prevent light leakage and distinguish a boundary between the adjacent first and second color filters CF1 and CF2.

The protective layer BFL may be disposed under the light-blocking layer BM and the first and second color filters CF1 and CF2. The protective layer BFL may cover the light-blocking layer BM and the first and second color filters CF1 and CF2. The protective layer BFL may protect the first and second color filters CF1 and CF2. For example, the protective layer BFL may include a silicon compound such as silicon oxide, silicon nitride, silicon oxynitride, and the like. These may be used alone or in combination with each other.

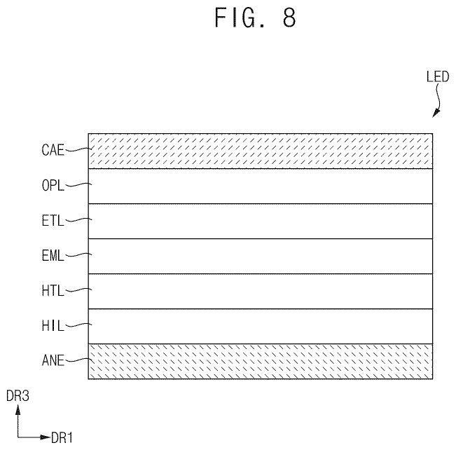

FIG. 8 is a cross-sectional view illustrating a light-emitting element of FIG. 5.

Referring to FIG. 8, the light-emitting element LED may include an anode electrode ANE, a hole injection layer HIL, a hole transport layer HTL, the light-emitting layer EML, an electron transport layer ETL, the organic protective layer OPL, and a cathode electrode CAE sequentially stacked along the third direction DR3. In this case, the light-emitting layer EML may include quantum dots and may emit light along the third direction DR3.

The first electrode E1 of FIG. 5 may correspond to the anode electrode ANE, the first functional layer FL1 of FIG. 5 may correspond to the hole injection layer HIL and the hole transport layer HTL, the second functional layer FL2 of FIG. 5 may correspond to the electron transport layer ETL, and the second electrode E2 of FIG. 5 may correspond to the cathode electrode CAE.

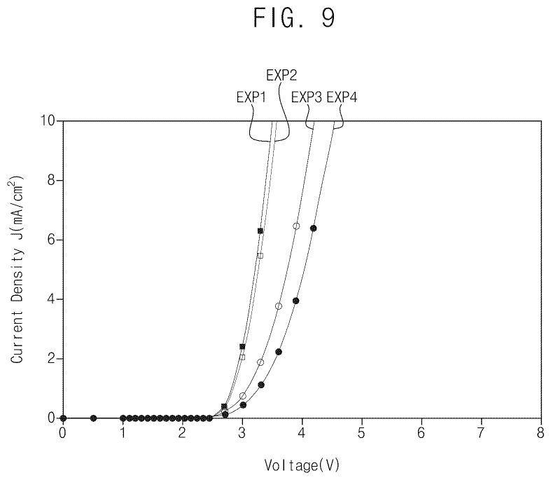

FIG. 9 is a graph for explaining changes in current density according to embodiments of the present disclosure.

Referring to FIGS. 5 and 9, in a first embodiment EXP1, a second embodiment EXP2, a third embodiment EXP3, and a fourth embodiment EXP4, the change in current density flowing through the light-emitting element LED (unit: milliamperes per square centimeter (mA/cm²)) according to the driving voltage (unit: voltage (V)) was measured. In the first embodiment EXP1, the first thickness TH1 of the central portion OPL_C of the organic protective layer OPL is about 0 angstrom (Å). In the second embodiment (EXP2), the first thickness TH1 of the central portion OPL_C of the organic protective layer OPL is about 60 angstrom (Å). In the third embodiment EXP3, the first thickness TH1 of the central portion OPL_C of the organic protective layer OPL is about 90 angstrom (Å). In the fourth embodiment EXP4, the first thickness TH1 of the central portion OPL_C of the organic protective layer OPL is about 120 angstrom (Å).

As a result, it can be confirmed that as the first thickness TH1 of the central portion OPL_C of the organic protective layer OPL becomes thicker, a phenomenon of the driving voltage being pushed occurs. Here, the phenomenon of the driving voltage being pushed denotes that the increase in the current density is relatively small as the driving voltage increases. If the phenomenon of the driving voltage being pushed occurs, the characteristics of the light-emitting element LED may deteriorate. However, FIG. 9 is merely an example to explain which as the first thickness TH1 of the center portion OPL_C of the organic protective layer OPL becomes thicker, the phenomenon of the driving voltage being pushed occurs, and if the first thickness TH1 of the center portion OPL_C of the organic protective layer OPL exceeds about 120 angstrom (Å), the characteristics of the light-emitting element LED may deteriorate.

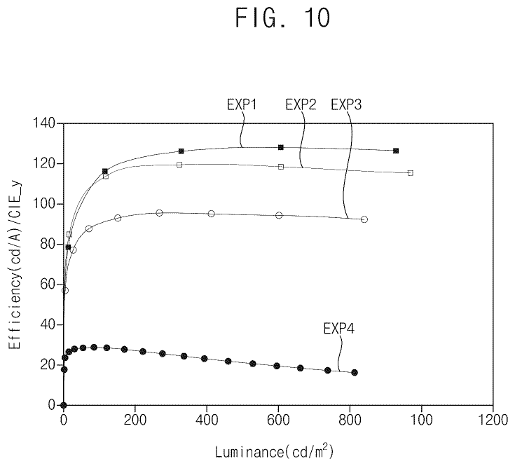

FIG. 10 is a graph for explaining changes in luminous efficiency according to embodiments of the present disclosure.

Referring to FIGS. 5 and 10, in a first embodiment EXP1, a second embodiment EXP2, a third embodiment EXP3, and a fourth embodiment EXP4, the change in luminous efficiency of the light-emitting element LED (unit: candela per ampere (cd/A)) according to luminance (unit: candela per square meter (cd/m²)) was measured. In the first embodiment EXP1, the first thickness TH1 of the central portion OPL_C of the organic protective layer OPL is about 0 angstrom (Å). In the second embodiment (EXP2), the first thickness TH1 of the central portion OPL_C of the organic protective layer OPL is about 60 angstrom (Å). In the third embodiment EXP3, the first thickness TH1 of the central portion OPL_C of the organic protective layer OPL is about 90 angstrom (Å). In the fourth embodiment EXP4, the first thickness TH1 of the central portion OPL_C of the organic protective layer OPL is about 120 angstrom (Å).

As a result, it can be confirmed that as the first thickness TH1 of the center portion OPL_C of the organic protective layer OPL becomes thicker, the luminous efficiency decreases. However, FIG. 10 is merely an example to explain which as the first thickness TH1 of the center portion OPL_C of the organic protective layer OPL becomes thicker, the luminous efficiency may decrease, and if the first thickness TH1 of the center portion OPL_C of the organic protective layer OPL exceeds about 120 angstrom (Å), the luminous efficiency may not be sufficient.

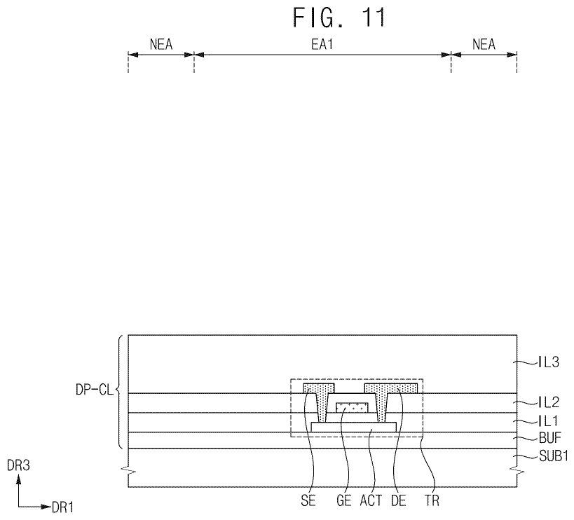

FIGS. 11, 12, 13, and 14 are cross-sectional views for explaining a method for manufacturing the display device of FIG. 5. Hereinafter, descriptions which overlap with those provided with reference to FIG. 5 will be omitted or simplified.

Referring to FIG. 11, the buffer layer BUF, the active pattern ACT, the first insulating layer IL1, the gate electrode GE, the second insulating layer IL2, the source electrode SE, the drain electrode DE, and the third insulating layer IL3 may be sequentially formed on the first substrate SUB1.

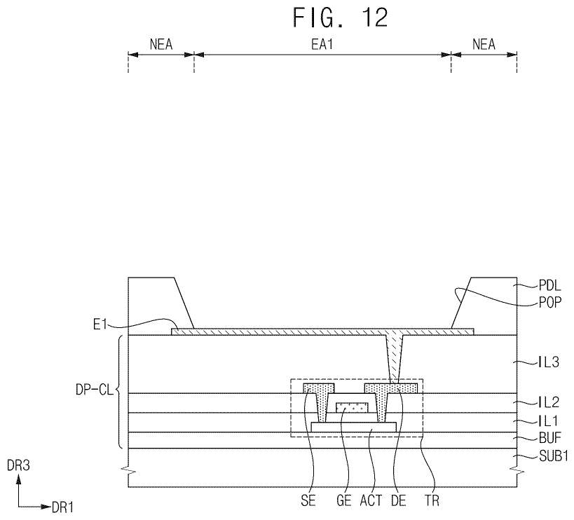

Referring to FIG. 12, the first electrode E1 may be formed in the first light-emitting area EA1 on the third insulating layer IL3. The pixel defining layer PDL may be formed on the third insulating layer IL3. The pixel opening POP exposing at least a portion of the upper surface of the first electrode E1 may be formed (or defined) in the pixel defining layer PDL. Specifically, a preliminary pixel defining layer covering the first electrode E1 may be entirely formed on the third insulating layer IL3, and the preliminary pixel defining layer may be etched to form the pixel defining layer PDL.

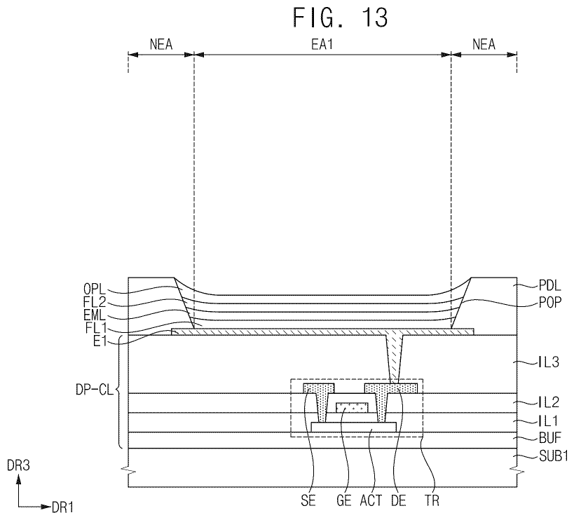

Referring to FIG. 13, in the pixel opening POP, the first functional layer FL1, the light-emitting layer EML, the second functional layer FL2, and the organic protective layer OPL may be sequentially formed in the thickness direction (i.e., the third direction DR3) on the first electrode E1. In an embodiment, each of the first functional layer FL1, the light-emitting layer EML, the second functional layer FL2, and the organic protective layer OPL may be formed through a solution process using a material for a solution process. Accordingly, the light-emitting element LED including the first electrode E1, the first functional layer FL1, the light-emitting layer EML, the second functional layer FL2, the organic protective layer OPL, and the second electrode E2 may be formed.

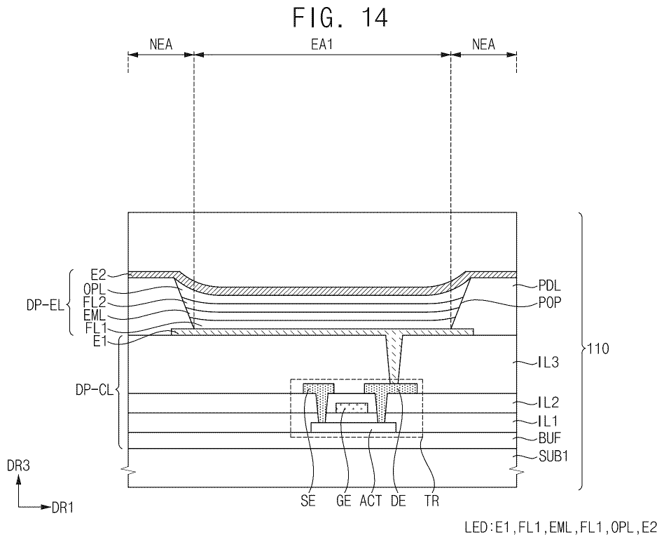

Referring to FIG. 14, the second electrode E2 may be formed on the pixel defining layer PDL and the organic protective layer OPL. The second electrode E2 may be formed entirely over the first light-emitting area EA1 and the non-light-emitting area NEA.

The encapsulation layer TFE may be formed on the second electrode E2. The encapsulation layer TFE may be formed entirely over the first light-emitting area EA1 and the non-light-emitting area NEA. The encapsulation layer TFE may include at least one inorganic layer and at least one organic layer. Accordingly, the display panel 110 including the circuit layer DP-CL, the light-emitting element layer DP-EL, and the encapsulation layer TFE may be formed.

Referring again to FIG. 5, the optical member PP including the second substrate SUB2, the first and second color filters CF1 and CF2 formed under the second substrate SUB2, the light-blocking layer BM formed under the first and second color filters CF1 and CF2, and the protective layer BFL formed under the light-blocking layer BM may be manufactured

The optical member PP may be attached onto the display panel 110. Accordingly, the display device DD illustrated in FIG. 5 may be manufactured.

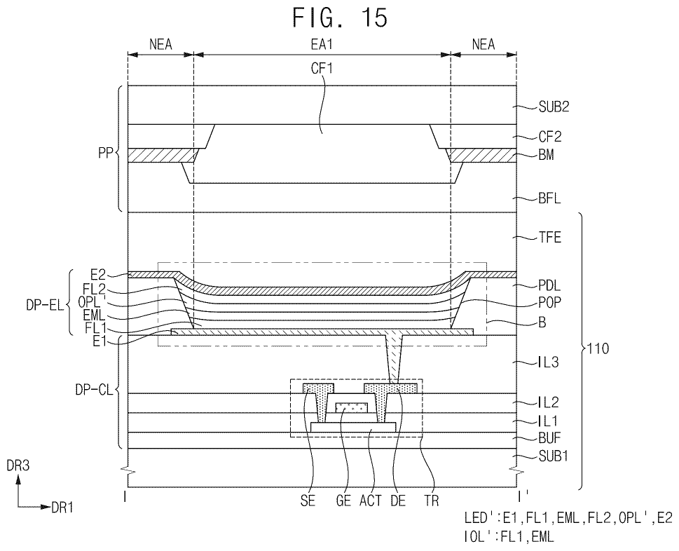

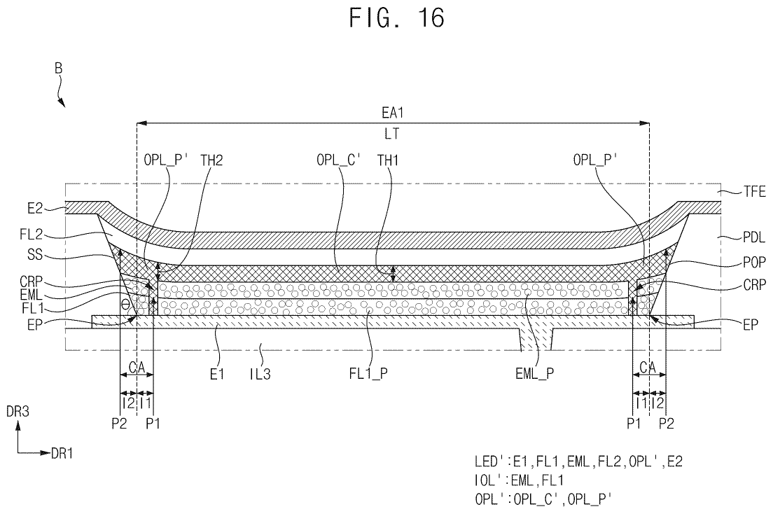

FIG. 15 is a cross-sectional view illustrating another example of a cross-section t aken along line I-I′ of FIG. 4. FIG. 16 is an enlarged cross-sectional view of area B of FIG. 15.

For example, FIG. 15 is a cross-sectional view illustrating the first light-emitting area EA1 of FIG. 4. The cross-sectional structure of the first light-emitting area EA1 of FIG. 15, which will be described later, may be substantially equally applied to the second light-emitting area EA2 and the third light-emitting area EA3 of FIG. 4.

Referring to FIGS. 1, 15, and 16, the display device DD may include the display panel 110 and the optical member PP. The display panel 110 may include the first substrate SUB1, the circuit layer DP-CL, the light-emitting element layer DP-EL, and the encapsulation layer TFE. The circuit layer DP-CL may include the buffer layer BUF, the transistor TR, and the first, second, and third insulating layers IL1, IL2, and IL3. The light-emitting element layer DP-EL may include the pixel defining layer PDL and a light-emitting element LED'. In addition, the optical member PP may include the second substrate SUB2, the first and second color filters CF1 and CF2, the light-blocking layer BM, and the protective layer BFL.

Here, the transistor TR may include the active pattern ACT, the gate electrode GE, the source electrode SE, and the drain electrode DE, and the light-emitting element LED′ may include a first electrode E1, a first functional layer FL1, a light-emitting layer EML, a second functional layer FL2, and a second electrode E2.

However, the display device DD described with reference to FIGS. 15 and 16 may be substantially the same as or similar to the display device DD described with reference to FIGS. 5 and 6, except for the structure of the light-emitting element LED'. Therefore, redundant descriptions are omitted or simplified.

The first electrode E1 may be disposed on the first light-emitting area EA1 on the third insulating layer IL3. In an embodiment, the first electrode E1 may be a cathode electrode. For example, the first electrode E1 may be patterned to correspond to each of the first, second, and third light-emitting areas EA1, EA2, and EA3 illustrated in FIG. 4. Alternatively, the first electrode E1 may be integrally formed over the first, second, and third light-emitting areas EA1, EA2, and EA3 provided as a single common layer.

The pixel defining layer PDL may be disposed on the third insulating layer IL3. The pixel defining layer PDL may overlap the non-emitting area NEA. The pixel opening POP exposing at least a portion of the upper surface of each of the first electrodes E1 may be defined in the pixel defining layer PDL. The pixel defining layer PDL may include an inorganic material and/or an organic material.

The components of the first functional layer FL1 will be described by taking as an example the case where the first electrode E1 is a cathode electrode and the second electrode E2 is an anode electrode.

The first functional layer FL1 may include an electron transport layer. The electron transport layer may transport electrons from the first electrode E1 to the light-emitting layer EML.

The electron transport layer may include a material for a solution process. In an embodiment, the material for the solution process of the electron transport layer may include an electron transport material such as a plurality of inorganic nanoparticles FL1_P. The inorganic nanoparticles FL1_P may serve to transport electrons injected from the first electrode E1. For example, the inorganic nanoparticles FL1_P may include a metal oxide.

For example, the first functional layer FL1 may be patterned to correspond to each of the first, second, and third light-emitting areas EA1, EA2, and EA3 illustrated in FIG. 4. Alternatively, the first functional layer FL1 may be integrally formed over the first, second, and third light-emitting areas EA1, EA2, and EA3 and the non-light-emitting area NEA illustrated in FIG. 4 provided as a single common layer.

The light-emitting layer EML may be disposed on the first functional layer FL1. The light-emitting layer EML may overlap the first light-emitting area EA1. Specifically, the light-emitting layer EML may be disposed in the pixel opening POP of the pixel defining layer PDL.

The light-emitting layer EML may include a material for a solution process. In an embodiment, the material for the solution process of the light-emitting layer EML may include a light-emitting material such as a plurality of quantum dots EML_P. For example, the quantum dots EML_P may emit light of a specific color (e.g., red).

For example, each of the quantum dots EML_P may have a core-shell structure including a core and a shell surrounding the core.

For example, the core of each of the quantum dots EML_P may include a group II-VI compound, a group III-V compound, a group IV-VI compound, a group IV element, a group IV compound, and/or the like. These may be used alone or in combination with each other. In an embodiment, the material included in the core and the material included in the shell may be different from each other. The shell of the quantum dot may include an oxide of a metal or non-metal, a semiconductor compound, and/or the like.

In FIG. 15 and FIG. 16, the first functional layer FL1 and the light-emitting layer EML may be collectively defined as an inorganic layer IOL'. That is, the inorganic layer IOL′ may include the first functional layer FL1 and the light-emitting layer EML.

In an embodiment, an angle θ between a side surface SS of the pixel defining layer PDL and the upper surface of the first electrode E1 covered by the pixel defining layer PDL may be in a range of about 50 to about 90 degrees. Preferably, the angle θ between the side surface SS of the pixel defining layer PDL and the upper surface of the first electrode E1 covered by the pixel defining layer PDL may be in a range of about 55 to about 90 degrees. If the angle θ between the side surface SS of the pixel defining layer PDL and the upper surface of the first electrode E1 covered by the pixel defining layer PDL is in a range of about 50 to about 90 degrees, an aperture ratio of the pixel opening POP may be relatively large. In this case, the luminous efficiency of the display device DD may be improved, and this may be advantageous for high-resolution implementation of the display device DD.

However, if the angle θ between the side surface SS of the pixel defining layer PDL and the upper surface of the first electrode E1 covered by the pixel defining layer PDL is in a range of about 50 to about 90 degrees, a crack point CRP may be formed (or defined) in the inorganic layer IOL′ in a crack generation area CA adjacent to an edge of the pixel opening POP after a drying and baking process for removing a solvent in the inorganic layer IOL'. In this case, if the second electrode E2 is formed directly on the inorganic layer IOL', the second electrode E2 may be disconnected due to the crack point CRP. In addition, if the second electrode E2 is formed directly on the inorganic layer IOL', the second electrode E2 may penetrate into the crack point CRP, which may increase leakage current. If the second electrode E2 is disconnected, luminance unevenness between the pixels may occur, and if the leakage current increases, the performance of the display panel 110 may deteriorate.

The crack generation area CA may be an area between a first point P1 of the inorganic layer IOL, which is spaced apart by a first horizontal length in one direction toward a center of the pixel opening POP from an end EP of the pixel defining layer PDL contacting the first electrode E1 and a second point P2 of the inorganic layer IOL, which is spaced apart by a second horizontal length I2 in a direction opposite to the one direction from the end EP of the pixel defining layer PDL. Here, the one direction may be a direction parallel to the major surface of the first substrate SUB1 defined by the first and second directions DR1 and DR2. In an embodiment, each of the first horizontal length I1 and the second horizontal length I2 may be about 10% or less of a length LT of the pixel opening POP in the first direction DR1.

In an embodiment, the light-emitting element LED′ may be disposed directly on the inorganic layer IOL′ in the pixel opening POP and may further include an organic protective layer OPL′ filling the crack point CRP. Accordingly, if forming the second electrode E2, disconnection of the second electrode E2 due to the crack point CRP may be minimized or reduced. In this case, the luminance unevenness between the pixels may be improved. In addition, since the organic protective layer OPL′ is filled in the crack point CRP, the current may be concentrated on the first light-emitting area EA1. In this case, the penetration of the second electrode E2 into the crack point CRP may be minimized or reduced, and thus the leakage current may be effectively reduced.

The organic protective layer OPL′ may include a center portion OPL_C′ corresponding to the center of the pixel opening POP and a peripheral portion OPL_P′ adjacent to an edge of the pixel opening POP. In an embodiment, the thickness TH1 and TH2 of the organic protective layer OPL′ may gradually increase from the center portion OPL_C′ to the peripheral portion OPL_P'. That is, the first thickness TH1 of the center portion OPL_C′ of the organic protective layer OPL′ may be thinner than the second thickness TH2 of the peripheral portion OPL_P'. The second thickness TH2 of the peripheral portion OPL_P′ of the organic protective layer OPL′ must be relatively thick so that the organic protective layer OPL′ may sufficiently fill the crack point CRP. In addition, the first thickness TH1 of the center portion OPL_C′ of the organic protective layer OPL′ must be relatively thin so that the characteristics of the light-emitting element LED′ may not be deteriorated.

In an embodiment, the first thickness TH1 of the central portion OPL_C′ of the organic protective layer OPL′ may be in a range of about 1 to about 120 angstrom (Å) or less. If the first thickness TH1 of the central portion OPL_C′ of the organic protective layer OPL′ is less than about 1 angstrom (Å), an overall thickness of the organic protective layer OPL′ may also be relatively thin. In this case, the organic protective layer OPL′ may not be sufficiently filled in the crack point CRP. If the first thickness TH1 of the center portion OPL_C′ of the organic protective layer OPL′ exceeds about 120 angstrom (Å), current may not flow well in the light-emitting element LED'.

In an embodiment, the organic protective layer OPL′ may include a material for the solution process including an organic insulating material. For example, the organic insulating material may include poly(ethylene glycol), poly(4-vinylpyridine), polyvinylpyrrolidone, polyethyleneimine, and/or the like. These may be used alone or in combination with each other. Alternatively, the organic protective layer OPL′ may include an organic semiconductor instead of the organic insulating material.

The second functional layer FL2 may be disposed on the organic protective layer OPL'. The second functional layer FL2 may overlap the first light-emitting area EA1. Specifically, the second functional layer FL2 may be disposed in the pixel opening POP of the pixel defining layer PDL.

The components of the second functional layer FL2 will be described by taking as an example the case where the first electrode E1 is a cathode electrode and the second electrode E2 is an anode electrode.

The second functional layer FL2 may include a hole transport layer. The hole transport layer may play a role in facilitating the injection of holes from the second electrode E2 to the light-emitting layer EML. In an embodiment, the hole transport layer may include a material for a solution process including a hole transport material.

The second functional layer FL2 may further include a hole injection layer in addition to the hole transport layer. In this case, the hole injection layer may be disposed between the second electrode E2 and the hole transport layer. The hole injection layer may improve hole injection characteristics into the hole transport layer without increasing the driving voltage. In an embodiment, the hole injection layer may include a material for a solution process. For example, the material for the solution process of the hole injection layer may include a general hole injection material known in the art.

For example, the second functional layer FL2 may be patterned to correspond to each of the first, second, and third light-emitting areas EA1, EA2, and EA3 illustrated in FIG. 4. Alternatively, the second functional layer FL2 may be integrally formed over the first, second, and third light-emitting areas EA1, EA2, and EA3 and the non-light-emitting area NEA illustrated in FIG. 4 provided as a single common layer.

That is, in the pixel opening POP, the inorganic layer IOL′, the organic protective layer OPL′, the second functional layer FL2, and the second electrode E2 may be disposed in this order along the thickness direction (i.e., the third direction DR3) on the first electrode E1.

The second electrode E2 may be disposed on the second functional layer FL2 and the pixel defining layer PDL. In an embodiment, the second electrode E2 may be an anode electrode.

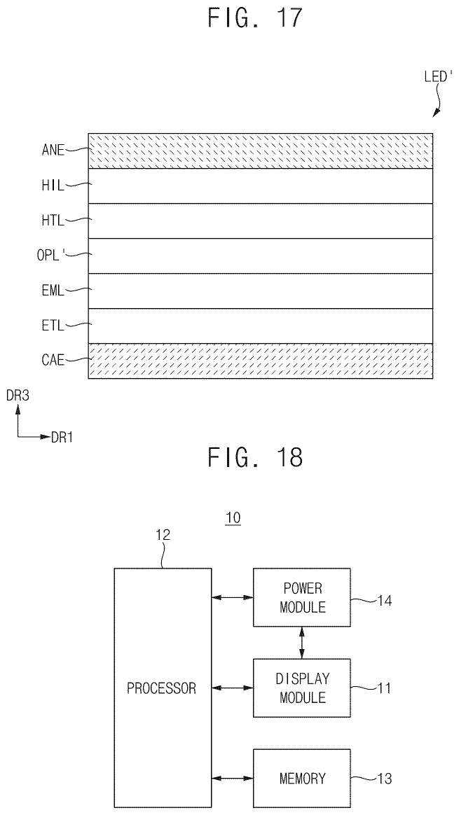

FIG. 17 is a cross-sectional view illustrating a light-emitting element of FIG. 15.

Referring to FIG. 17, the light-emitting element LED′ may include a cathode electrode CAE, an electron transport layer ETL, the light-emitting layer EML, the organic protective layer OPL', a hole injection layer HIL, a hole transport layer HTL, and an anode electrode ANE sequentially stacked along the third direction DR3. In this case, the light-emitting layer EML may include quantum dots and may emit light along the third direction DR3.

The first electrode E1 of FIG. 15 may correspond to the cathode electrode CAE, the first functional layer FL1 of FIG. 15 may correspond to the electron transport layer ETL, the second functional layer FL2 of FIG. 15 may correspond to the hole injection layer HIL and the hole transport layer HTL, and the second electrode E2 of FIG. 15 may correspond to the anode electrode ANE.

Referring again to FIGS. 1 to 17, the display device DD according to embodiments of the present disclosure may include the first electrode E1 disposed in a light-emitting area (e.g., the first light-emitting area EA, the second light-emitting area EA2, or the third light-emitting area EA3), the pixel defining layer PDL covering the edge of the first electrode E1 and defining the pixel opening POP exposing at least a portion of the upper surface of the first electrode E1, a first functional layer (e.g., the first functional layer FL1 in FIG. 6 or the second functional layer FL2 in FIG. 16) disposed in the pixel opening POP, the inorganic layer IOL and IOL′ disposed in the pixel opening POP and including the crack generation area CA adjacent to the edges of the pixel opening POP and in which the crack point CRP is defined, the organic protective layer OPL and OPL′ disposed directly on the inorganic layer IOL and IOL′ in the pixel opening POP and filing the crack point CRP, and the second electrode E2 disposed on the organic protective layer OPL and OPL′ and the pixel defining layer PDL.

The inorganic layer IOL and IOL′ may include a light-emitting layer including the plurality of quantum dots EML_P and a second functional layer (e.g., the second functional layer FL2 of FIG. 6 or the first functional layer FL1 of FIG. 16) including the plurality of inorganic nanoparticles FL2_P and FL1_P.

Accordingly, if forming the second electrode E2, disconnection of the second electrode E2 due to the crack point CRP may be minimized or reduced. In this case, luminance unevenness between the pixels may be improved. In addition, by filling the crack point CRP with the organic protective layer OPL and OPL', the current may be concentrated in the light-emitting area. In this case, the penetration of the second electrode E2 into the crack point CRP may be minimized or reduced, and thus the leakage current may be effectively reduced.

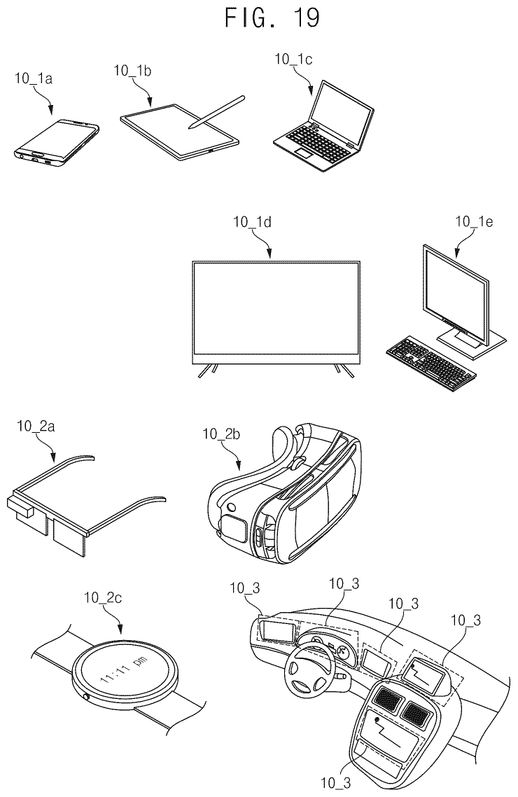

FIG. 18 is a block diagram illustrating an electronic device according to embodiments of the present disclosure.

Referring to FIG. 18, an electronic device 10 according to embodiments of the present disclosure may include a display module 11, a processor 12, a memory 13, and a power module 14. A display device (e.g., the display device DD of FIG. 1) according to embodiments of the present disclosure may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), and an image signal processor (ISP).

The memory 15 may store data information necessary for the operation of the processor 12 or the display module 11. If the processor 12 executes the application stored in the memory 15, an input image data (e.g., IDAT in FIG. 2) and/or a control signal (e.g., CTRL in FIG. 2) may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

FIG. 19 is a schematic diagram illustrating an electronic device according to various embodiments.

Referring to FIGS. 18 and 19, various electronic devices 10 to which display devices according to the embodiments are applied may include not only image display electronic devices such as a smartphone 10_1a, a tablet PC 100_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

As described above, while the present disclosure has been explained with reference to exemplary embodiments, it will be understood by those of ordinary skill in the art that various modifications and changes can be made thereto without departing from the spirit and scope of the invention as defined in the following claims.

The present disclosure may be applied to various display devices which can be equipped with a display device. For example, the present disclosure may be applied to high-resolution smartphones, mobile phones, smart pads, smart watches, tablet PCs, vehicle navigation systems, televisions, computer monitors, and notebook computers.

What is claimed is:

1. A display device comprising:
a first electrode disposed in a light-emitting area on a substrate;
a pixel defining layer covering an edge of the first electrode and defining a pixel opening exposing at least a portion of an upper surface of the first electrode;
a first functional layer disposed in the pixel opening;
an inorganic layer disposed in the pixel opening and including a crack generation area adjacent to edges of the pixel opening and in which a crack point is defined;
an organic protective layer disposed directly on the inorganic layer in the pixel opening and filing the crack point; and
a second electrode disposed on the organic protective layer and the pixel defining layer.

2. The display device of claim 1, wherein an angle between the upper surface of the first electrode covered by the pixel defining layer and a side surface of the pixel defining layer is in a range of about 50 to about 90 degrees.

3. The display device of claim 1, wherein the crack generation area is an area between a first point of the inorganic layer, which is spaced apart by a first horizontal length in one direction toward a center of the pixel opening from an end of the pixel defining layer contacting the first electrode, and a second point of the inorganic layer, which is spaced apart by a second horizontal length in a direction opposite to the one direction from the end of the pixel defining layer,
the one direction is a direction parallel to a major surface of the substrate, and
each of the first horizontal length and the second horizontal length is about 10% or less of a length of the pixel opening in the one direction.

4. The display device of claim 1, wherein the crack point is defined continuously along edges of the pixel opening in the crack generation area in a plan view.

5. The display device of claim 1, wherein the inorganic layer includes:
a light-emitting layer including a plurality of quantum dots; and
a second functional layer including a plurality of inorganic nanoparticles.

6. The display device of claim 1, wherein the organic protective layer includes a central portion corresponding to the center of the pixel opening and a peripheral portion adjacent to the edges of the pixel opening, and
a thickness of the central portion is thinner than a thickness of the peripheral portion.

7. The display device of claim 6, wherein the thickness of the central portion of the organic protective layer is in a range of about 1 to about 120 angstrom (Å).

8. The display device of claim 1, wherein the organic protective layer includes a central portion corresponding to the center of the pixel opening and a peripheral portion adjacent to the edges of the pixel opening, and
a thickness of the organic protective layer gradually increases from the central portion to the peripheral portion.

9. The display device of claim 1, wherein the organic protective layer includes a material for a soluble process including an organic insulating material.

10. The display device of claim 1, wherein in the pixel opening, the first functional layer, the inorganic layer, the organic protective layer, and the second electrode are disposed in this order on the first electrode along a thickness direction of the display device.

11. The display device of claim 10, wherein the first electrode is an anode electrode and the second electrode is a cathode electrode.

12. The display device of claim 10, wherein the first functional layer includes a hole injection layer and a hole transport layer.

13. The display device of claim 1, wherein in the pixel opening, the inorganic layer, the organic protective layer, the first functional layer, and the second electrode are disposed in this order on the first electrode along a thickness direction of the display device.

14. The display device of claim 13, wherein the first electrode is a cathode electrode and the second electrode is an anode electrode.

15. The display device of claim 13, wherein the first functional layer includes a hole injection layer and a hole transport layer.

16. An electronic device comprising:
a display device including:
a first electrode disposed in a light-emitting area on a substrate;
a pixel defining layer covering an edge of the first electrode and defining a pixel opening exposing at least a portion of an upper surface of the first electrode;
a first functional layer disposed in the pixel opening;
an inorganic layer disposed in the pixel opening and including a crack generation area adjacent to edges of the pixel opening and in which a crack point is defined;
an organic protective layer disposed directly on the inorganic layer in t pixel opening and filing the crack point; and
a second electrode disposed on the organic protective layer and the pixel defining layer, and
a processor, which controls the display device by providing input image data and a control signal to the display device.

17. The electronic device of claim 16, wherein an angle between the upper surface of the first electrode covered by the pixel defining layer and a side surface of the pixel defining layer is in a range of about 50 to about 90 degrees.

18. The electronic device of claim 16, wherein the crack generation area is an area between a first point of the inorganic layer, which is spaced apart by a first horizontal length in one direction toward a center of the pixel opening from an end of the pixel defining layer contacting the first electrode, and a second point of the inorganic layer, which is spaced apart by a second horizontal length in a direction opposite to the one direction from the end of the pixel defining layer,
the one direction is a direction parallel to a major surface of the substrate, and
each of the first horizontal length and the second horizontal length is about 10% or less of a length of the pixel opening in the one direction.

19. The electronic device of claim 16, wherein the inorganic layer includes:
a light-emitting layer including a plurality of quantum dots; and
a second functional layer including a plurality of inorganic nanoparticles.

20. The electronic device of claim 16, wherein the organic protective layer includes a central portion corresponding to the center of the pixel opening and a peripheral portion adjacent to the edges of the pixel opening, and
a thickness of the central portion is thinner than a thickness of the peripheral portion.
